(19) United States
(12) Patent Application Publication
(10) Pub. No.: US 2024/0365484 A1
(43) Pub. Date: Oct. 31, 2024

(54) DISPLAY DEVICE

(71) Applicant: LG Display Co., Ltd., Seoul (KR)

(72) Inventors: Seung Bum HEO, Paju-si (KR); Young Eun KIM, Paju-si (KR); Hyo Sup EUM, Paju-si (KR)

(21) Appl. No.: 18/646,192

(22) Filed: Apr. 25, 2024

(30) Foreign Application Priority Data
Apr. 27, 2023 (KR) 10-2023-0055337

(51) Int. Cl. H05K 5/02; H01L 25/16; H05K 5/00; H05K 5/03

(52) U.S. Cl. CPC H05K 5/0217; H01L 25/167; H05K 5/0021; H05K 5/03

(57) ABSTRACT

According to some embodiments of the present specification, a display device may include a display panel including a display area where a plurality of sub-pixels are disposed and a non-display area, a back cover disposed under the display panel, and a roller and a rail disposed between the display panel and the back cover, wherein the rail may be disposed between two display panels, and the roller may be disposed on each of two side surfaces of each rail.

### CROSS-REFERENCE TO RELATED APPLICATION

This application claims priority to and the benefit of Korean Patent Application No. 10-2023-0055337, filed on Apr. 27, 2023, the disclosure of which is incorporated herein by reference in its entirety.

### BACKGROUND

### Technical Field

The present specification relates to a display device, and more specifically, to a display device using a light emitting diode.

### Description of Related Art

Display devices used in computer monitors, TVs, mobile phones, and the like include organic light emitting diode (OLED) display devices which emit light by themself, liquid crystal display (LCD) devices which require a separate light source, and the like.

The scope of application of display devices is becoming more diverse from computer monitors and TVs to personal portable devices, and research on display devices with a large display area and reduced volume and weight is being conducted. In addition, recently, display devices including light emitting diodes (LEDs) have been attracting attention as next-generation display devices. The LED is made of an inorganic material rather than an organic material, and thus is highly reliable and has a longer lifetime than LCD devices or OLED display devices. In addition, the LED has not only a fast lighting speed, but also excellent luminous efficiency, and excellent stability due to strong impact resistance, and may display high-brightness images.

### BRIEF SUMMARY

When a large-scale display device is configured by tiling a plurality of display panels, a distance between the display panels may be changed due to heating caused by driving the display panels. Therefore, the inventors of the present disclosure have invented a display device in which the distance between the display panels is restorable.

The present specification is also directed to providing a display device, which may conveniently align each display panel and a cover bottom (or bottom cover) or the cover bottom and a cabinet when each display and the cover bottom or the cover bottom and the cabinet are deformed and restored.

The objects of the present specification are not limited to the above-described objects, and other objects that are not mentioned will be able to be clearly understood by those skilled in the art from the following description.

A display device according to an embodiment of the present specification may include a display panel including a display area in which a plurality of sub-pixels are disposed and a non-display area, a back cover disposed under the display panel, and a roller and a rail disposed between the display panel and the back cover, wherein the rail may be disposed between two display panels, and the roller may be disposed on each of two side surfaces.

### BRIEF DESCRIPTION OF THE SEVERAL VIEWS OF THE DRAWINGS

FIG. 1 is a schematic configuration diagram of a display device according to one embodiment of the present specification.

FIG. 2 is a perspective view of a tiling display device according to one embodiment of the present specification.

FIG. 3 is a plan view of a display panel of the display device according to one embodiment of the present specification.

FIG. 4 is a partial cross-sectional view of the display device according to one embodiment of the present specification.

FIG. 5 is a cross-sectional view of the display device according to one embodiment of the present specification.

FIG. 6 is an exploded perspective view of the display device according to one embodiment of the present specification.

FIG. 7 is a plan view of a portion of the display device according to one embodiment of the present specification.

FIG. 8 is a plan view of another portion of the display device according to one embodiment of the present specification.

FIG. 9A is an enlarged view of a portion of the display device according to one embodiment of the present specification.

FIG. 9B is an enlarged view of a portion of a display device according to another embodiment of the present disclosure.

FIG. 10 is a side view of the display device according to one embodiment of the present specification.

FIGS. 11A, 11B, and 11C are schematic plan views showing a thermal deformation process according to one embodiment of the present specification.

FIG. 12 is a view of a rail according to an embodiment of the present specification.

FIG. 13 is a view of a rail according to another embodiment of the present specification.

FIG. 14 is an exploded perspective view of a display device according to another embodiment of the present specification.

### DETAILED DESCRIPTION

Advantages and features of the present specification and methods for achieving them will become clear with reference to embodiments described below in detail in conjunction with the accompanying drawings. However, the present specification is not limited to the embodiments disclosed below but can be implemented in various different forms, these embodiments are merely provided to make the disclosure of the present specification complete and fully inform those skilled in the art to which the present specification pertains of the scope of the present specification, and the scope of the appended claims is not limited by the disclosure.

Since shapes, sizes, ratios, angles, numbers, and the like disclosed in the drawings for describing the embodiments of the present specification are illustrative, the present specification is not limited to the illustrated items. The same reference number indicates the same components throughout the specification. In addition, in describing the present specification, when it is determined that the detailed description of a related known technology may unnecessarily obscure the gist of the present specification, detailed description thereof will be omitted. When terms “comprises,” “has,” “consists of,” and the like described in the present specification are used, other parts may be added unless “only” is used. When a component is expressed in the singular, it includes a case in which the component is provided as a plurality of components unless specifically stated otherwise.

In construing a component, the component is construed as including the margin of error even when there is no separate explicit description.

When the positional relationship is described, for example, when the positional relationship between two parts is described using the term “on,” “above,” “under,” “next to,” or the like, one or more other parts may be positioned between the two parts unless the term “immediately” or “directly” is used.

Although terms such as first, second, and the like are used to describe various components, these components are not limited by these terms. These terms are only used to distinguish one component from another. Therefore, a first component described below may be a second component within the technical spirit of the present specification.

Features of various embodiments of the present specification can be coupled or combined partially or entirely, and various technological interworking and driving are possible, and the embodiments may be implemented independently of each other or implemented together in an associated relationship.

Hereinafter, various embodiments of the present specification will be described in detail with reference to the accompanying drawings.

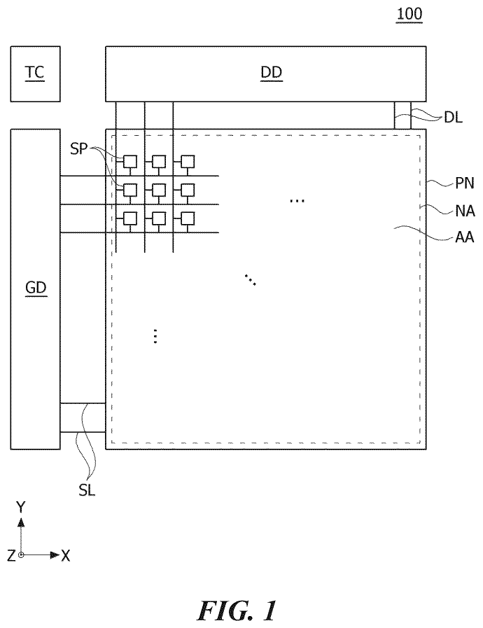

FIG. 1 is a schematic configuration diagram of a display device according to one embodiment of the present specification.

For convenience of description, only a display panel PN, a gate driver GD, a data driver DD, and a timing controller TC among various components of a display device 100 are shown in FIG. 1.

Referring to FIG. 1, the display device 100 includes the display panel PN including a plurality of sub-pixels SP, the gate driver GD and the data driver DD for supplying various signals to the display panel PN, and the timing controller TC for controlling the gate driver GD and the data driver DD.

The gate driver GD supplies scan signals to a plurality of scan lines SL according to a plurality of gate control signals provided from the timing controller TC. Although FIG. 1 shows that one gate driver GD is disposed to be spaced apart from one side of the display panel PN, the number and arrangement of gate drivers GD are not limited thereto.

The data driver DD converts image data received from the timing controller TC into data voltages using a reference gamma voltage according to a plurality of data control signals provided from the timing controller TC. The data driver DD may supply the converted data voltages to a plurality of data lines DL.

The timing controller TC arranges the image data input from the outside and supplies the sorted image data to the data driver DD. The timing controller TC may generate gate control signals and data control signals using synchronization signals input from the outside, such as a dot clock signal, a data enable signal, and horizontal/vertical synchronization signals. In addition, the timing controller TC may control the gate driver GD and the data driver DD by supplying the generated gate control signals and data control signals to the gate driver GD and the data driver DD, respectively.

The display panel PN is a component for showing images to a user and includes a plurality of sub-pixels SP. In the display panel PN, a plurality of scan lines SL and a plurality of data lines DL intersect each other, and each of the plurality of sub-pixels SP is connected to the scan line SL and the data line DL. In addition, although not shown in the drawing, each of the plurality of sub-pixels SP may be connected to a high potential power supply line, a low potential power supply line, a reference line, and the like.

The display panel PN may include a display area AA and a non-display area NA.

The display area AA is an area where the images are displayed in the display device 100. The plurality of sub-pixels SP forming a plurality of pixels PX and a circuit for driving the plurality of sub-pixels SP may be disposed in the display area AA. The plurality of sub-pixels SP are the minimum unit forming the display area AA, and n sub-pixels SP may form one pixel PX. A light emitting element, a thin film transistor for driving the light emitting element, and the like may be disposed in each of the plurality of sub-pixels SP. A plurality of light emitting elements may be defined differently depending on the type of display panel PN. For example, when the display panel PN is an inorganic light emitting display panel, the light emitting element may be a light emitting diode (LED) or a micro light emitting diode (micro LED).

A plurality of lines through which various signals are transmitted to the plurality of sub-pixels SP are disposed in the display area AA. For example, the plurality of lines may include the plurality of data lines DL through which the data voltages are supplied to each of the plurality of sub-pixels SP, the plurality of scan lines SL through which the scan signal is supplied to each of the plurality of sub-pixels SP, and the like. The plurality of scan lines SL may extend in one direction in the display area AA and may be connected to the plurality of sub-pixels SP, and the plurality of data lines DL may extend in a direction which differs from the one direction in the display area AA and may be connected to the plurality of sub-pixels SP. In addition, although the low potential power supply line, the high potential power supply line, and the like may be further disposed in the display area AA, the present specification is not limited thereto.

The non-display area NA is an area where the images are not displayed and can be defined as an area extending from the display area AA. Link lines and pad electrodes for transmitting signals to the sub-pixel SP of the display area AA or driving ICs, such as a gate driver IC and a data driver IC, may be disposed in the non-display area NA.

However, the non-display area NA may be positioned on a back surface, that is, a surface without the sub-pixel SP of the display panel PN, or may be omitted, and is not limited to those shown in the drawing.

Meanwhile, the drivers, such as the gate driver GD, the data driver DD, and the timing controller TC may be connected to the display panel PN in any of various ways. For example, the gate driver GD may be mounted in the non-display area NA of one side surface of the display area AA in a gate in panel (GIP) method and mounted between the plurality of sub-pixels SP in the display area AA in a gage in active area (GIA) method. For example, the data driver DD and the timing controller TC may be formed on a separate flexible film and a printed circuit board and electrically connected to the display panel PN by bonding the flexible film and the printed circuit board to pad electrodes formed in the non-display area NA of the display panel PN.

When the gate driver GD is mounted in the GIP method and the data driver DD and the timing controller TC transmit signals to the display panel PN through the pad electrode in the non-display area NA, the non-display area NA for arranging the gate driver GD and the pad electrodes needs an area of a predetermined level or more, and thus a bezel may increase.

In contrast, when the gate driver GD is mounted inside the display area AA in the GIA method and the flexible film and the printed circuit board are bonded to a back surface of the display panel PN by forming the signal lines on a front surface of the display panel PN with the pad electrodes on the back surface of the display panel PN, the non-display area NA of the front surface of the display panel PN can be minimally reduced. In other words, when the gate driver GD, the data driver DD, and the timing controller TC are connected to the display panel PN in the above methods, a substantially bezel-less screen can be implemented.

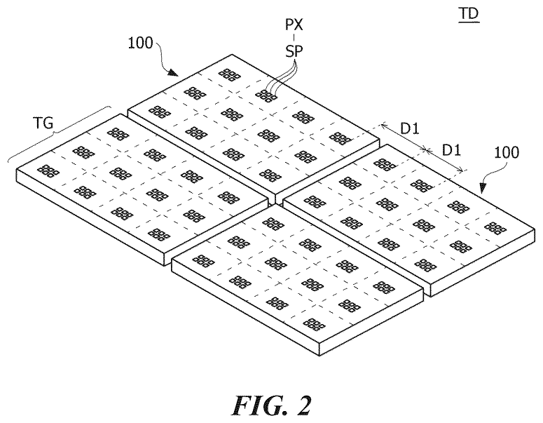

FIG. 2 is a perspective view of a tiling display device according to one embodiment of the present specification. Referring to FIG. 2, a tiling display device TD with a large screen can be implemented by connecting a plurality of display devices 100.

A large-area tiling display device TD can be implemented by re-connecting two or more tiling groups TG in which two or more display devices 100 are connected.

In this case, when the tiling display device TD is implemented using the display device 100 with the minimized bezel, it is possible to minimize a seam area where any image is not displayed between the display devices 100, thereby improving display quality.

For example, a plurality of sub-pixels SP may form one pixel PX, and a distance D1 between an outermost pixel PX of one display device 100 and an outermost pixel PX of another display device 100 adjacent to the one display device 100 can be implemented to be the same as a distance D1 between the pixels PX in one display device 100. Therefore, it is possible to minimize a seam area because a constant distance D1 between a pixel PX of a display device 100 and a pixel PX of an adjacent display device 100 is formed.

However, FIG. 2 is an example, and the display device 100 according to one embodiment of the present specification may be a general display device 100 with a bezel, but is not limited thereto.

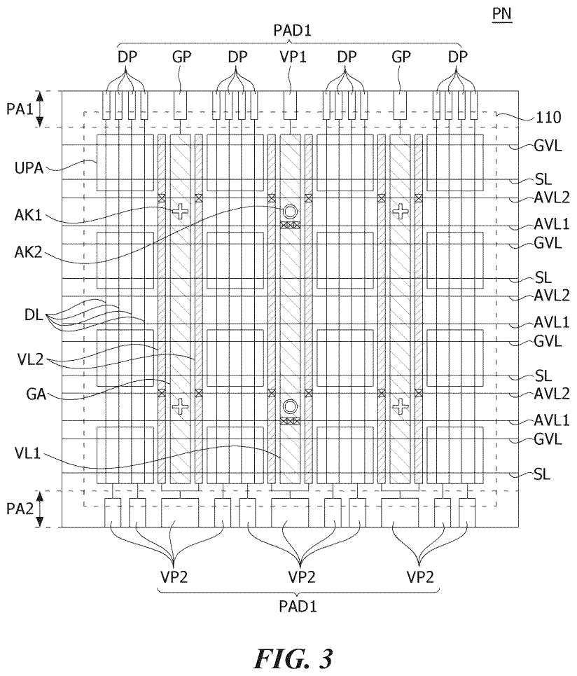

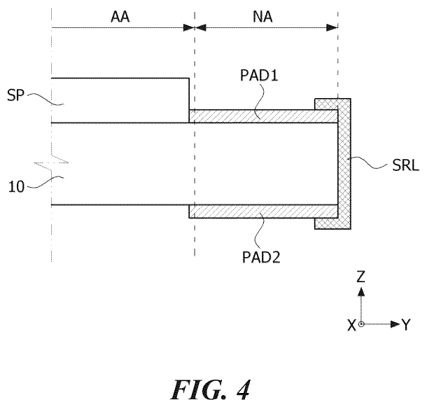

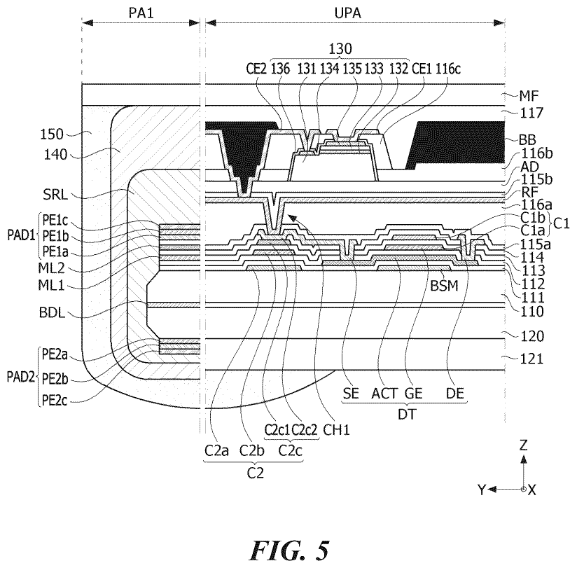

FIG. 3 is a plan view of a display panel of the display device according to one embodiment of the present specification. FIGS. 4 and 5 are cross-sectional views of the display device according to one embodiment of the present specification.

Referring to FIGS. 3, 4, and 5, the display panel PN includes a first substrate 110. The first substrate 110 is a substrate for supporting components disposed above the display device 100 and may be an insulating substrate. A plurality of pixels PX may be formed on the first substrate 110 to display images.

For example, the first substrate 110 may be made of glass or resin. In addition, the first substrate 110 may be made of polymer or plastic. In some embodiments, the first substrate 110 may be made of a flexible plastic material.

A plurality of pixel areas UPA, a plurality of gate driving areas GA, and a plurality of pad areas PA1 and PA2 are disposed on the first substrate 110. Among them, the plurality of pixel areas UPA and the plurality of gate driving areas GA may be included in the display area AA of the display panel PN disposed between the plurality of pad areas PA1 and PA2.

First, the plurality of pixels area UPA are areas where the plurality of pixels PX are disposed. The plurality of pixel areas UPA may be disposed in a form of a plurality of rows and a plurality of columns. Each of the plurality of pixels PX disposed in the plurality of pixel areas UPA includes a plurality of sub-pixels SP. Each of the plurality of sub-pixels SP may independently emit light by including a light emitting element 130 and a pixel circuit. The plurality of sub-pixels SP may include a plurality of sub-pixels SP for emitting light of different colors. For example, the plurality of sub-pixels SP may include a red sub-pixel, a blue sub-pixel, and a green sub-pixel, but are not limited thereto.

The plurality of gate driving areas GA are areas where gate driving circuits are disposed. The gate driving circuit may be mounted in the display area (AA) in the GIA method. For example, the gate driving areas GA may be formed in row and/or column directions between the plurality of pixel areas UPA. The gate driving circuit formed in the gate driving area GA may provide the scan signals to the plurality of scan lines SL.

The gate driving circuit disposed in the gate driving area GA may include a circuit for outputting the scan signals. In this case, the gate driving circuit may include, for example, a plurality of transistors and/or capacitors. Here, active layers of the plurality of transistors may be made of a semiconductor material, such as an oxide semiconductor, amorphous silicon, or polysilicon, but are not limited thereto. In this case, the active layers of the plurality of transistors may be made of the same material or made of different materials. In addition, the active layers of the transistors of the gate driver may be made of the same material as the active layers of various transistors of the pixel circuit or made of different materials.

The plurality of pad areas PA1 and PA2 are areas where the plurality of first pad electrodes PAD1 are disposed. The plurality of first pad electrodes PAD1 may transmit various signals to various lines extending in the column direction in the display area AA. For example, the plurality of first pad electrodes PAD1 may include a data pad DP for transmitting the data voltage to the data line DL, a gate pad GP for transmitting a clock signal, a start signal, a gate low voltage, a gate high voltage, and the like for driving the gate driving circuit to the gate driving circuit, a high potential power supply pad VP1 for transmitting a high potential power supply voltage to a high potential power supply line VL1, and a low potential power supply pad VP2 for transmitting a low potential power supply voltage to a low potential power supply line VL2.

The plurality of pad areas PA1 and PA2 include a first pad area PA1 positioned at an upper edge of the display panel PN and a second pad area PA2 of the display panel PN. In this case, different types of first pad electrodes PAD1 may be disposed in the first pad area PA1 and the second pad area PA2. For example, the data pad DP, the gate pad GP, and the high potential power supply pad VP1 among the plurality of first pad electrodes PAD1 may be disposed in the first pad area PA1, and the low potential power supply pad VP2 may be disposed in the second pad area PA2.

In this case, each of the plurality of first pad electrodes PAD1 may be formed to have a different size. For example, the plurality of data pads DP connected to correspond to the plurality of data lines DL, respectively may have a relatively smaller width, and the high potential power supply pad VP1, the low potential power supply pad VP2, and the gate pad GP may have a relatively greater width. However, the widths of the data pad DP, the gate pad GP, the high potential power supply pad VP1, and the low potential power supply pad VP2 shown in FIG. 3 are exemplary, and the size of the first pad electrode PAD1 may be configured in various ways, but is not limited thereto.

Meanwhile, to reduce the bezel of the display panel PN, an edge of the display panel PN may be removed by being cut. It is possible to reduce a bezel area by initially forming the plurality of pixels PX, the plurality of lines, and the plurality of first pad electrodes PAD1 on the first substrate 110 and grinding an edge portion of the first substrate 110. Since a portion of the first substrate 110 may be initially removed in the grinding process, the first substrate 110 with a smaller size (a quadrangular dotted line portion) may be formed. At this time, portions of the plurality of first pad electrodes PAD1 and the lines disposed at the edge of the first substrate 110 may be removed. Therefore, only a portion of the plurality of first pad electrodes PAD1 may remain on the first substrate 110.

Next, the plurality of data lines DL extending in the column direction from the plurality of first pad electrodes PAD1 are disposed on the first substrate 110 of the display panel PN. The plurality of data lines DL may extend from the plurality of data pads DP of the first pad area PA1 toward the plurality of pixel areas UPA. The plurality of data lines DL extend in the column direction and may be disposed to overlap the plurality of pixel areas UPA. Therefore, the plurality of data lines DL may transmit the data voltages to each pixel circuit of the plurality of sub-pixels SP.

A plurality of high potential power supply lines VL1 extending in the column direction are disposed on the first substrate 110 of the display panel PN. Some of the plurality of high potential power supply lines VL1 may extend from the high potential power supply pad VP1 of the first pad area PA1 toward the plurality of pixel areas UPA to transmit the high potential power supply voltage to the light emitting element 130 of each of the plurality of sub-pixels SP. In addition, the others of the plurality of high potential power supply line VL1 may be electrically connected to another high potential power supply line VL1 through an auxiliary high potential power supply line AVL1 to be described below. For convenience of description, although FIG. 3 shows that one high potential power supply line VL1 and one high potential power supply pad VP1 are disposed, a plurality of high potential power supply lines VL1 and a plurality of high potential power supply pads VP1 may be disposed.

A plurality of low potential power supply lines VL2 extending in the column direction are disposed on the first substrate 110 of the display panel PN. At least some of the plurality of low potential power supply lines VL2 may extend from the low potential power supply pad VP2 of the second pad area PA2 toward the plurality of pixel areas UPA to transmit the low potential power supply voltage to the pixel circuit of each of the plurality of sub-pixels SP. In addition, the others of the plurality of low potential power supply line VL2 may be electrically connected to another low potential power supply line VL2 through an auxiliary low potential power supply line AVL2 to be described below.

The plurality of scan lines SL extending in the row direction are disposed on the first substrate 110 of the display panel PN. The plurality of scan lines SL may extend in the row direction and may be disposed to cross the plurality of pixel areas UPA and the plurality of gate driving areas GA. The plurality of scan lines SL may transmit the scan signals from the gate driving circuits to the pixel circuits of the plurality of sub-pixels SP.

A plurality of auxiliary high potential power supply lines AVL1 extending in the row direction are disposed on the first substrate 110 of the display panel PN. A plurality of auxiliary high potential power supply lines AVL1 may be disposed in an area between the plurality of pixel areas UPA. The plurality of auxiliary high potential power supply lines AVL1 extending in the row direction may be electrically connected to the plurality of high potential power supply lines VL1 extending in the column direction through contact holes to form a mesh structure. Therefore, the plurality of auxiliary high potential power supply lines AVL1 and the plurality of high potential power supply lines VL1 may be configured to form the mesh structure, thereby minimizing voltage drop and voltage deviation.

A plurality of auxiliary low potential power supply lines AVL2 extending in the row direction are disposed on the first substrate 110 of the display panel PN. The plurality of auxiliary low potential power supply lines AVL2 may be disposed in the area between the plurality of pixel areas UPA. The plurality of auxiliary low potential power supply lines AVL2 extending in the row direction may be electrically connected to the plurality of low potential power supply lines VL2 extending in the column direction through contact holes to form a mesh structure. Therefore, the plurality of auxiliary low potential power supply lines AVL2 and the plurality of low potential power supply lines VL2 may be configured to form the mesh structure, thereby reducing resistances of the lines and minimizing voltage deviation.

The plurality of gate driving lines GVL extending in the row direction are disposed on the first substrate 110 of the display panel PN. The plurality of gate driving lines GVL may transmit various signals to the gate driving circuits of the gate driving areas GA. The plurality of gate driving lines GVL may include lines for transmitting the clock signal, the start signal, the gate high voltage, the gate low voltage, and the like of the gate driving circuit. Therefore, various signals may be transmitted from the gate driving line GVL to the gate driver GD to drive the gate driving circuit.

A plurality of alignment keys AK1 and AK2 are disposed in an area between the plurality of pixel areas UPA in the display panel PN. The plurality of alignment keys AK1 and AK2 are used for alignment in a manufacturing process of the display panel PN. The plurality of alignment keys AK1 and AK2 include the first alignment key AK1 and the second alignment key AK2.

The first alignment key AK1 may be disposed in the gate driving area GA among the areas between the plurality of pixel areas UPA. The first alignment key AK1 can be used to check alignment positions of the plurality of light emitting elements 130. For example, the first alignment key AK1 may be formed in a cross shape, but is not limited thereto.

The second alignment key AK2 may be disposed to overlap the high potential power supply line VL1 among the areas between the plurality of pixel areas UPA. Since a hole overlapping the second alignment key AK2 may be formed in the high potential power supply line VL1, the second alignment key AK2 and the high potential power supply line VL1 may be distinguished. The second alignment key AK2 can be used to align the display panel PN and a donor. The display panel PN and the donor may be aligned using the second alignment key AK2, and the plurality of light emitting elements 130 of the donor may be transferred to the display panel PN. For example, the second alignment key AK2 may be formed in a circular ring shape, but is not limited thereto.

FIG. 4 is a partial cross-sectional view of the display device according to one embodiment of the present specification.

Referring to FIG. 4, a plurality of pad electrodes for transmitting various signals to the plurality of sub-pixels SP are disposed in the non-display area NA of the display panel PN. For example, a first pad electrode PAD1 for transmitting the signals to the plurality of sub-pixels SP is disposed in the non-display area NA of the front surface of the substrate 10 of the display panel PN, and a second pad electrode PAD2 electrically connected to driving components, such as a flexible film and a printed circuit board, is disposed in the non-display area NA of the back surface of the display panel PN.

In other words, only a pad area where the first pad electrode PAD1 is disposed of the non-display area NA may be minimally formed on the front surface of the display panel PN on which the images are displayed.

In this case, although not shown in the drawing, various signal lines connected to the plurality of sub-pixels SP, such as scan lines SL or data lines DL, may extend from the display area AA to the non-display area NA and may be electrically connected to the first pad electrode PAD1.

In addition, a side line SRL is disposed along a side surface of the display panel PN. The side line SRL may electrically connect the first pad electrode PAD1 of the front surface of the display panel PN with the second pad electrode PAD2 of the back surface of the display panel PN. Therefore, signals transmitted from the driving components on the back surface of the display panel PN may be transmitted to the plurality of sub-pixels SP through the second pad electrode PAD2, the side line SRL, and the first pad electrode PAD1. Therefore, by forming a signal transmission path between the side and back surfaces on the front surface of the display panel PN, it is possible to minimize an area of the non-display area NA on the front surface of the display panel PN.

Referring to FIG. 5, the substrate 10 shown in FIG. 4 may include a first substrate 110 and a second substrate 120. A pixel circuit for driving the light emitting element 130 is disposed in each of the plurality of sub-pixels SP on the first substrate 110. The pixel circuit may include a plurality of thin film transistors and a plurality of capacitors. For convenience of description, although FIG. 5 shows only the driving transistor DT, a first capacitor C1, and a second capacitor C2 among the components of the pixel circuit, the pixel circuit may further include a switching transistor, a sensing transistor, an emission control transistor, and the like, but is not limited thereto.

First, a light blocking layer BSM is disposed on the first substrate 110. The light blocking layer BSM can minimize a leakage current by blocking light incident on active layers ACT of the plurality of transistors. For example, the light blocking layer BSM may be disposed under the active layer ACT of the driving transistor DT to block the light incident on the active layer ACT. When light is radiated to the active layer ACT, a leakage current may be generated, thereby reducing the reliability of the transistor. Therefore, it is possible to improve the reliability of the driving transistor DT by arranging the light blocking layer BSM for blocking light on the first substrate 110. The light blocking layer BSM may be made of an opaque conductive material, such as copper (Cu), aluminum (Al), molybdenum (Mo), nickel (Ni), titanium (Ti), chromium (Cr), or an alloy thereof, but is not limited thereto.

A buffer layer 111 is disposed on the light blocking layer BSM. The buffer layer 111 can reduce the penetration of moisture or impurities through the first substrate 110. The buffer layer 111 may be formed of, for example, a single layer or multiple layers of silicon oxide (SiOₓ) or silicon nitride (SiNₓ), but is not limited thereto. However, the buffer layer 111 may be omitted depending on the type of first substrate 110 or the type of thin film transistor, but is not limited thereto.

The driving transistor DT including the active layer ACT, a gate electrode GE, a source electrode SE, and a drain electrode DE is disposed on the buffer layer 111.

First, the active layer ACT of the driving transistor DT is disposed on the buffer layer 111. The active layer ACT may be made of a semiconductor material such as oxide semiconductor, amorphous silicon, or polysilicon, but is not limited thereto. In addition, although not shown in the drawing, in addition to the driving transistor DT, other transistors, such as a switching transistor, a sensing transistor, and an emission control transistor, may be additionally disposed, and active layers of these transistors may also be made of a semiconductor material, such as an oxide semiconductor, amorphous silicon, or polysilicon, but is not limited thereto. In addition, the active layers of the transistors included in the pixel circuit, such as the driving transistor DT, the switching transistor, the sensing transistor, and the emission control transistor, may be made of the same material or may be made of different materials.

A gate insulating layer 112 is disposed on the active layer ACT. The gate insulating layer 112 is an insulating layer for electrically insulating the active layer ACT and the gate electrode GE and may be formed of a single layer or multiple layers of silicon oxide (SiOₓ) or silicon nitride (SiNₓ), but is not limited thereto.

The gate electrode GE is disposed on the gate insulating layer 112. The gate electrode GE may be made of a conductive material, such as copper (Cu), aluminum (Al), molybdenum (Mo), nickel (Ni), titanium (Ti), chromium (Cr), or an alloy thereof, but is not limited thereto.

A first interlayer insulating layer 113 and a second interlayer insulating layer 114 are disposed on the gate electrode GE. The first interlayer insulating layer 113 and the second interlayer insulating layer 114 have contact holes for connecting each of the source electrode SE and the drain electrode DE of the driving transistor DT to the active layer ACT. The first interlayer insulating layer 113 and the second interlayer insulating layer 114 are insulating layers for protecting components disposed thereunder and may be formed of a single layer or multiple layers of silicon oxide (SiOₓ) or silicon nitride (SiNₓ), but are not limited thereto.

The source electrode SE and the drain electrode DE electrically connected to the active layer ACT are disposed on the second interlayer insulating layer 114. The source electrode SE is connected to the second capacitor C2 and the first electrode 134 of the light emitting element 130, and the drain electrode DE is connected to another component of the pixel circuit. The source electrode SE and the drain electrode DE may be made of a conductive material, such as copper (Cu), aluminum (Al), molybdenum (Mo), nickel (Ni), titanium (Ti), chromium (Cr), or an alloy thereof, but are not limited thereto.

Next, the first capacitor C1 is disposed on the gate insulating layer 112. The first capacitor C1 includes a 1-1 capacitor electrode C1a and a 1-2 capacitor electrode C1b.

First, the 1-1 capacitor electrode C1a is disposed on the gate insulating layer 112. The 1-1 capacitor electrode C1a may be formed integrally with the gate electrode GE of the driving transistor DT.

The 1-2 capacitor electrode C1b is disposed on the first interlayer insulating layer 113. The 1-2 capacitor electrode C1b is disposed to overlap the 1-1 capacitor electrode C1a with the first interlayer insulating layer 113 interposed therebetween.

Therefore, the first capacitor C1 may be connected to the gate electrode GE of the driving transistor DT to maintain a voltage of the gate electrode GE of the driving transistor DT for a predetermined period.

Next, the second capacitor C2 is disposed on the first substrate 110. The second capacitor C2 includes a 2-1 capacitor electrode C2a, a 2-2 capacitor electrode C2b, and a 2-3 capacitor electrode C2c. The second capacitor C2 includes the 2-1 capacitor electrode C2a as a lower capacitor electrode, the 2-2 capacitor electrode C2b as a middle capacitor electrode, and the 2-3 capacitor electrode C2c as an upper capacitor electrode.

The 2-1 capacitor electrode C2a is disposed on the first substrate 110. The 2-1 capacitor electrode C2a may be disposed on the same layer as the light blocking layer BSM and may be made of the same material.

The 2-2 capacitor electrode C2b is disposed on the buffer layer 111 and the gate insulating layer 112. The 2-2 capacitor electrode C2b may be disposed on the same layer as the gate electrode GE and may be made of the same material.

The 2-3 capacitor electrode C2c is disposed on the first interlayer insulating layer 113. The 2-3 capacitor electrode C2c may include a first layer C2c1 and a second layer C2c2. The first layer C2c1 of the 2-3 capacitor electrode C2c may be made of the same material as the 1-2 capacitor electrode C1b on the same layer as the 1-2 capacitor electrode C1b. The first layer C2c1 may be disposed to overlap the 2-1 capacitor electrode C2a and the 2-2 capacitor electrode C2b with the first interlayer insulating layer 113 interposed therebetween.

The second layer C2c2 of the 2-3 capacitor electrode C2c is disposed on the second interlayer insulating layer 114. The second layer C2c2 is a portion extending from the source electrode SE of the driving transistor DT and may be connected to the first layer C2c1 through the contact hole in the second interlayer insulating layer 114.

Therefore, the second capacitor C2 may be electrically connected between the source electrode SE of the driving transistor DT and the light emitting element 130 to increase a capacitance inherent in the light emitting element 130 and allow light with higher brightness to emit from the light emitting element 130.

A first passivation layer 115a is disposed on the driving transistor DT, the first capacitor C1, and the second capacitor C2. The first passivation layer 115a is an insulating layer for protecting components under the first passivation layer 115a and may be made of an inorganic material, such as silicon oxide (SiOₓ) or silicon nitride (SiNₓ), but is not limited thereto.

A first planarization layer 116a is disposed on the first passivation layer 115a. The first planarization layer 116a may planarize an upper portion of the pixel circuit including the driving transistor DT. The first planarization layer 116a may be formed of a single layer or a double layer and may be made of, for example, benzocyclobutene or an acryl-based organic material, but is not limited thereto.

A reflector RF is disposed on the first planarization layer 116a. The reflector RF is a component for reflecting light emitted from the plurality of light emitting elements 130 onto the first substrate 110 and may be formed in a shape corresponding to each of the plurality of sub-pixels SP. One reflector RF may be disposed to cover most of the area of one sub-pixel SP. The reflector RF may reflect the light emitted from the light emitting element 130 and at the same time, can be used as an electrode for electrically connecting the light emitting element 130 with the pixel circuit. Specifically, the reflector RF may be electrically connected to the source electrode SE of the driving transistor DT and the second capacitor C2 through a first contact hole CHI of the first planarization layer 116a and the first passivation layer 115a. In addition, the reflector RF may be electrically connected to the first electrode 134 of the light emitting element 130 through a second connection electrode CE2. Therefore, the reflector RF may electrically connect the driving transistor DT with the first electrode 134 of the light emitting element 130. However, instead of connecting the first electrode 134 of the light emitting element 130 with the driving transistor DT, the reflector RF may electrically connect the second electrode 135 of the light emitting element 130 with the high potential power supply line VL1, but is not limited thereto.

The reflector RF may include any of various conductive layers in consideration of light reflection efficiency and resistance. For example, although the reflector RF can use an opaque conductive layer, such as silver (Ag), aluminum (Al), molybdenum (Mo), titanium (Ti), or an alloy thereof and a transparent conductive layer, such as indium tin oxide (ITO), together, a structure of the reflector RF is not limited thereto.

A second passivation layer 115b is disposed on the reflector RF. The second passivation layer 115b is an insulating layer for protecting components under the second passivation layer 115b and may be formed of a single layer or multiple layers of silicon oxide (SiOₓ) or silicon nitride (SiNₓ), but is limited thereto.

An adhesive layer AD is disposed on the second passivation layer 115b. The adhesive layer AD may be formed on the front surface of the first substrate 110 to fix the light emitting element 130 disposed on the adhesive layer AD. The adhesive layer AD may be made of a photocurable adhesive material which may be cured by light. For example, the adhesive layer AD may be made of an acrylic-based material containing a photosensitive agent, but is not limited thereto. The adhesive layer AD may be formed on the entire surface of the first substrate 110 excluding the pad areas PA1 and PA2 where the first pad electrode PAD1 is disposed.

The plurality of light emitting elements 130 are disposed in each of the plurality of sub-pixels SP on the adhesive layer AD. The light emitting element 130 is a device for emitting light by a current, may include the red light emitting element 130 for emitting red light, the green light emitting element 130 for emitting green light, and the blue light emitting element 130 for emitting blue light, and can implement light of various colors including a white color in combination thereof. For example, the light emitting element 130 may be an LED or a micro LED, but is not limited thereto.

The plurality of light emitting elements 130 include a first semiconductor layer 131, a light emitting layer 132, a second semiconductor layer 133, the first electrode 134, and the second electrode 135.

The first semiconductor layer 131 is disposed on the adhesive layer AD, and the second semiconductor layer 133 is disposed on the first semiconductor layer 131. The first semiconductor layer 131 and the second semiconductor layer 133 may be layers formed by doping n-type and p-type impurities into a specific material. For example, the first semiconductor layer 131 and the second semiconductor layer 133 may each be a layer in which a material, such as gallium nitride (GaN), indium aluminum phosphide (InAlP), or gallium arsenide (GaAs), is doped with n-type and p-type impurities. In addition, although the p-type impurity may be magnesium, zinc (Zn), beryllium (Be), or the like, and the n-type impurity may be silicon (Si), germanium, tin (Sn), or the like, the present disclosure are not limited thereto.

The light emitting layer 132 is disposed between the first semiconductor layer 131 and the second semiconductor layer 133. The light emitting layer 132 may emit light by receiving holes and electrons from the first semiconductor layer 131 and the second semiconductor layer 133. The light emitting layer 132 may be formed in a single-layer or multi-quantum well (MQW) structure and may be made of, for example, indium gallium nitride (InGaN) or gallium nitride (GaN), but is not limited thereto.

The first electrode 134 is disposed on the first semiconductor layer 131. The first electrode 134 is an electrode for electrically connecting the driving transistor DT with the first semiconductor layer 131. In this case, the first semiconductor layer 131 may be a semiconductor layer doped with n-type impurities, and the first electrode 134 may be a cathode. The first electrode 134 may be disposed on an upper surface of the first semiconductor layer 131 exposed from the light emitting layer 132 and the second semiconductor layer 133. The first electrode 134 may be made of a conductive material, for example, a transparent conductive material, such as ITO or indium zinc oxide (IZO), or an opaque conductive material, such as titanium (Ti), gold (Au), silver (Ag), copper (Cu), or an alloy thereof, but is not limited thereto.

The second electrode 135 is disposed on the second semiconductor layer 133. The second electrode 135 may be disposed on an upper surface of the second semiconductor layer 133. The second electrode 135 is an electrode for electrically connecting the high potential power supply line VL1 with the second semiconductor layer 133. In this case, the second semiconductor layer 133 may be a semiconductor layer doped with p-type impurities, and the second electrode 135 may be an anode. The second electrode 135 may be made of a conductive material, for example, a transparent conductive material, such as ITO or IZO, or an opaque conductive material, such as titanium (Ti), gold (Au), silver (Ag), copper (Cu), or an alloy thereof, but is not limited thereto.

Next, an encapsulation film 136 for surrounding the first semiconductor layer 131, the light emitting layer 132, the second semiconductor layer 133, the first electrode 134, and the second electrode 135 is disposed. The encapsulation film 136 may be made of an insulating material and can protect the first semiconductor layer 131, the light emitting layer 132, and the second semiconductor layer 133. In addition, a contact hole for exposing the first electrode 134 and the second electrode 135 may be formed in the encapsulation film 136 so that the first connection electrode CE1 and the second connection electrode CE2 may be electrically connected to the first electrode 134 and the second electrode 135.

Meanwhile, a portion of the side surface of the first semiconductor layer 131 may be exposed from the encapsulation film 136. The light emitting element 130 manufactured on a wafer may be separated from the wafer and transferred to the display panel PN. However, in the process of separating the light emitting element 130 from the wafer, a portion of the encapsulation film 136 may be peeled off. For example, a portion of the encapsulation film 136 adjacent to a lower edge of the first semiconductor layer 131 of the light emitting element 130 is peeled in the process of separating the light emitting element 130 from the wafer, and thus a portion of a lower side surface of the first semiconductor layer 131 may be exposed to the outside. However, even when a lower portion of the light emitting clement 130 is exposed from the encapsulation film 136, the first connection electrode CE1 and the second connection electrode CE2 are formed after a second planarization layer 116b and a third planarization layer 116c covering the side surface of the first semiconductor layer 131 are formed, and thus it is possible to reduce a short defect.

Next, the second planarization layer 116b and the third planarization layer 116c are disposed on the adhesive layer AD and the light emitting element 130.

The second planarization layer 116b may overlap portions of side surface portions of the plurality of light emitting elements 130 to fix and protect the plurality of light emitting elements 130. The second planarization layer 116b may be formed using a halftone mask. Therefore, the second planarization layer 116b may be formed to have a step.

Specifically, a portion of the second planarization layer 116b disposed relatively adjacent to the light emitting element 130 may be formed to have a relatively smaller thickness, and a portion disposed relatively far from the light emitting element 130 may be formed to have a relatively greater thickness. The portion of the second planarization layer 116b disposed adjacent to the light emitting element 130 may be disposed to surround the light emitting element 130 and may be in contact with the side surface of the light emitting element 130. Therefore, in the process of separating the light emitting element 130 from the wafer and transferring the light emitting element 130 to the display panel PN, the portion in which the encapsulation film 136 for protecting the side surface of the first semiconductor layer 131 of the light emitting element 130 has been peeled may be covered with the second planarization layer 116b. Therefore, it is possible to prevent contact and short defects between the connection electrodes CE1 and CE2 and the first semiconductor layer 131 in the future.

The third planarization layer 116c may be formed to cover the second planarization layer 116b and the upper portion of the light emitting element 130, and the contact hole to which the first electrode 134 and the second electrode 135 of the light emitting element 130 are exposed may be formed in the third planarization layer 116c. The first electrode 134 and the second electrode 135 of the light emitting element 130 may be exposed from the third planarization layer 116c, and the third planarization layer 116c may be disposed in a portion of an area between the first electrode 134 and the second electrode 135 to reduce a short defect. The second planarization layer 116b and the third planarization layer 116c may be formed of a single layer or multiple layers and may be made of, for example, photoresist or an acryl-based organic material, but are not limited thereto.

Meanwhile, the third planarization layer 116c may cover only the light emitting clement 130 and an area adjacent to the light emitting element 130. The third planarization layer 116c may be disposed in the area of the sub-pixel SP surrounded by a bank BB and may be disposed in an island shape. Therefore, the bank BB may be disposed on a portion of the upper surface of the second planarization layer 116b, and the third planarization layer 116c may be disposed on the remaining portion of the upper surface of the second planarization layer 116b.

The first connection electrode CE1 and the second connection electrode CE2 are disposed on the third planarization layer 116c. The first connection electrode CE1 is an electrode for electrically connecting the second electrode 135 of the light emitting element 130 with the high potential power supply line VL1. The first connection electrode CE1 may be electrically connected to the second electrode 135 of the light emitting element 130 through the contact hole formed in the third planarization layer 116c.

The second connection electrode CE2 is an electrode for electrically connecting the first electrode 134 of the light emitting element 130 with the driving transistor DT. The second connection electrode CE2 may be connected to the reflector RF of each of the plurality of sub-pixels SP through the contact hole formed in the third planarization layer 116c, the second planarization layer 116b, the adhesive layer AD, and the second passivation layer 115b. In this case, since the reflector RF is also connected to the source electrode SE of the driving transistor DT, the source electrode SE of the driving transistor DT and the first electrode 134 of the light emitting element 130 may be electrically connected.

The bank BB is disposed on the first and second connection electrodes CE1 and CE2 and the second planarization layer 116b exposed from the third planarization layer 116c. The bank BB may be disposed to be spaced a predetermined distance from the light emitting element 130, and at least a portion thereof may overlap the reflector RF. For example, the bank BB may cover a portion of the second connection electrode CE2 formed in the contact hole of the third planarization layer 116c and the second planarization layer 116b. In addition, the bank BB may be disposed on the second planarization layer 116b, for example, at a predetermined distance from the light emitting clement 130. In this case, the bank BB and the third planarization layer 116c may be spaced apart from each other on a portion of the second planarization layer 116b with a relatively smaller thickness. In other words, an end of the bank BB and an end of the third planarization layer 116c may be disposed to be spaced apart from each other on the portion of the second planarization layer 116b with a relatively smaller thickness formed by a halftone mask process.

The bank BB may be made of an opaque material to reduce color mixing between the plurality of sub-pixels SP and for example, may be made of a black resin, but is not limited thereto.

Meanwhile, a thickness of the portion of the bank BB, which is formed in the contact hole of the third planarization layer 116c and the second planarization layer 116b and covers a portion of the second connection electrode CE2, may differ from a thickness of the portion disposed on the second planarization layer 116b. Specifically, in the case of the portion of the bank BB, which covers a portion of the second connection electrode CE2 formed in the contact hole of the third planarization layer 116c and the second planarization layer 116b, since the contact hole is formed from the second passivation layer 115b to the third planarization layer 116c, the bank BB may be disposed under the light emitting element 130, that is, at a position lower than the light emitting element 130. Therefore, the thickness of the portion of the bank BB covering the portion of the second connection electrode CE2 formed in the contact hole of the third planarization layer 116c and the second planarization layer 116b may be greater than the thickness of the portion of the bank BB disposed on the second planarization layer 116b.

A first protective layer 117 is disposed on the first connection electrode CE1, the second connection electrode CE2, and the bank BB. The first protective layer 117 is a layer for protecting components under the first protective layer 117 and may be formed of a single layer or multiple layers of translucent epoxy, silicon oxide (SiOₓ), or silicon nitride (SiNₓ), but is not limited thereto.

A plurality of first pad electrodes PAD1 are disposed in the first pad area PA1 and the second pad area PA2 of the first substrate 110. Each of the plurality of first pad electrodes PAD1 may be formed of a plurality of conductive layers. For example, each of the plurality of first pad electrodes PAD1 includes a first conductive layer PE1a, a second conductive layer PE1b, and a third conductive layer PE1c.

First, the first conductive layer PE1a is disposed on the second interlayer insulating layer 114. The first conductive layer PE1a may be made of the same conductive material as the source electrode SE and the drain electrode DE, such as copper (Cu), aluminum (Al), molybdenum (Mo), and nickel (Ni), titanium (Ti), chromium (Cr), or alloys thereof, but is not limited thereto.

The first passivation layer 115a is disposed on the first conductive layer PE1a, and the second conductive layer PE1b is disposed on the first passivation layer 115a. The second conductive layer PE1b may be made of the same conductive material as the reflector RF and may be made of, for example, silver (Ag), aluminum (Al), molybdenum (Mo), or an alloy thereof, but is not limited thereto.

The third conductive layer PE1c is disposed on the second conductive layer PE1b. The third conductive layer PE1c may be made of the same conductive material as the first connection electrode CE1 and the second connection electrode CE2 and may be made of, for example, a transparent conductive material, such as ITO or IZO, or the like, but is not limited thereto.

In this case, although not shown in the drawing, some of the plurality of conductive layers of the first pad electrode PAD1 may be electrically connected to a plurality of lines on the first substrate 110 to supply various signals to the plurality of lines and the plurality of sub-pixels SP. For example, the first conductive layer PE1a and/or the second conductive layer PE1b of the first pad electrode PAD1 may be connected to the data line DL, the high potential power supply line VL1, the low potential power supply line VL2, and the like disposed in the display area AA to transmit signals to each of the data line DL, the high potential power supply line VL1, and the low potential power supply line VL2.

In addition, a first metal layer ML1, a second metal layer ML2, and a plurality of insulating layers may be disposed under the first pad electrode PAD1 together. A step difference due to the first pad electrode PAD1 may be adjusted by arranging the first metal layer ML1, the second metal layer ML2, and the plurality of insulating layers under the first pad electrode PAD1. For example, the buffer layer 111, the gate insulating layer 112, the first metal layer ML1, the first interlayer insulating layer 113, and the second metal layer ML2 may be sequentially disposed between the first pad electrode PAD1 and the first substrate 110. The first metal layer ML1 may be made of the same conductive material as the gate electrode GE, and the second metal layer ML2 may be made of the same conductive material as the 1-2 capacitor electrode C1b. However, the plurality of insulating layers and the first and second metal layers under the first pad electrode PAD1 may be omitted according to the design, but the present specification is not limited thereto.

The second substrate 120 is disposed under the first substrate 110. The second substrate 120 is a substrate for supporting components disposed under the display device 100 and may be an insulating substrate. For example, the second substrate 120 may be made of glass or resin. In addition, the second substrate 120 may be made of polymer or plastic. The second substrate 120 may be made of the same material as the first substrate 110. In some embodiments, the second substrate 120 may be made of a flexible plastic material.

A bonding layer BDL is disposed between the first substrate 110 and the second substrate 120. The bonding layer BDL may be made of a material which is cured through various curing methods to bond the first substrate 110 and the second substrate 120. The bonding layer BDL may be disposed only on a partial area between the first substrate 110 and the second substrate 120 or disposed on the entire area.

A plurality of second pad electrodes PAD2 may be disposed on a back surface of the second substrate 120. The plurality of second pad electrodes PAD2 are electrodes for transmitting signals transmitted from the driving components disposed at a back surface side of the second substrate 120 to the plurality of side lines SRL, the plurality of first pad electrodes PAD1 on the first substrate 110, and the plurality of lines. The plurality of second pad electrodes PAD2 may be electrically connected to the side lines SRL disposed at an end portion of the second substrate 120 to cover an end portion of the second substrate 120 in the non-display area NA.

In this case, the plurality of second pad electrodes PAD2 may also be disposed to correspond to the plurality of pad areas PA1 and PA2. Each of the plurality of first pad electrodes PAD1 may be disposed to correspond to each of the plurality of second pad electrodes PAD2, and then the first pad electrode PAD1 and the second pad electrode PAD2 overlapping each other may be electrically connected through the side line SRL.

Each of the plurality of second pad electrodes PAD2 includes a plurality of conductive layers. For example, each of the plurality of second pad electrodes PAD2 includes a fourth conductive layer PE2a, a fifth conductive layer PE2b, and a sixth conductive layer PE2c.

First, the fourth conductive layer PE2a is disposed under the second substrate 120. The fourth conductive layer PE2a may be made of a conductive material, such as copper (Cu), aluminum (Al), molybdenum (Mo), nickel (Ni), titanium (Ti), chromium (Cr), or an alloy thereof, but is not limited thereto.

The fifth conductive layer PE2b is disposed under the fourth conductive layer PE2a. The fifth conductive layer PE2b may be made of a conductive material, such as copper (Cu), aluminum (Al), molybdenum (Mo), nickel (Ni), titanium (Ti), chromium (Cr), or an alloy thereof, but is not limited thereto.

The sixth conductive layer PE2c is disposed under the fifth conductive layer PE2b. The sixth conductive layer PE2c may be made of a conductive material, for example, a transparent conductive material, such as ITO or IZO, but is not limited thereto.

In addition, a first support EIA is disposed in an area of the second substrate 120 where the plurality of second pad electrodes PAD2 are not disposed. The first support EIA may protect various lines and driving components formed on the second substrate 120. The first support EIA may be made of an organic insulating material, such as benzocyclobutene or an acryl-based organic insulating material, but is not limited thereto.

In addition, the first support EIA may be used to dissipate heat generated from the display panel PN to the outside and may be made of any one selected from aluminum (Al), copper (Cu), zinc (Zn), silver (Ag), gold (Au), and iron (Fe), or an alloy thereof as a metal material with high thermal conductivity, but is not limited thereto.

Driving components including a plurality of flexible films COF and a printed circuit board PCB may be disposed at the back surface side of the second substrate 120. The plurality of flexible films COF are components on which various components, such as a data driver IC, are disposed on a flexible base film to supply signals to the plurality of sub-pixels SP. The printed circuit board PCB is a component which is electrically connected to the plurality of flexible films to supply signals to driving ICs. Various components for supplying various signals to the diving ICs may be disposed on the printed circuit board.

For example, the fourth conductive layer PE2a and/or the fifth conductive layer PE2b of the second pad electrode PAD2 may extend toward the plurality of flexible films disposed at the back surface side of the second substrate 120 and electrically connected to the plurality of flexible films, and the plurality of flexible films may supply various signals to the plurality of side lines SRL, the plurality of first pad electrodes PAD1, the plurality of lines, and the plurality of sub-pixels SP through the second pad electrode PAD2. Therefore, the signal transmitted from the driving component may be transmitted to the signal lines and the plurality of sub-pixels SP on the front surface of the substrate 110 through the plurality of second pad electrodes PAD2 of the second substrate 120, the side line SRL, and the plurality of first pad electrodes PAD1 of the first substrate 110.

Next, the plurality of side lines SRL are disposed on the side surfaces of the first substrate 110 and the second substrate 120. The plurality of side lines SRL may electrically connect the plurality of first pad electrodes PAD1 formed on the upper surface of the first substrate 110 with the plurality of second pad electrodes PAD2 formed on the back surface of the second substrate 120. The plurality of side lines SRL may be disposed to surround the side surface of the display device 100. Each of the plurality of side lines SRL may cover the first pad electrode PAD1 of the end portion of the first substrate 110, the side surface of the first substrate 110, the side surface of the second substrate 120, and the second pad electrode PAD2 of the end portion of the second substrate 120. For example, the plurality of side lines SRL may be formed by a pad printing method using conductive ink, for example, conductive ink containing silver (Ag), copper (Cu), molybdenum (Mo), and chromium (Cr).

A side insulating layer 140 for covering the plurality of side lines SRL is disposed. The side insulating layer 140 may be formed to cover the side line SRL on the upper surface of the first substrate 110, the side surface of the first substrate 110, the side surface of the second substrate 120, and the back surface of the second substrate 120. The side insulating layer 140 may protect the plurality of side lines SRL.

Meanwhile, there may be a problem that when the plurality of side lines SRL are made of a metal material, external light is reflected from the plurality of side lines SRL, or light emitted from the light emitting element 130 is reflected from the plurality of side lines SRL, which is visible by the user. Therefore, the side insulating layer 140 includes a black material, thereby suppressing reflection of external light. For example, the side insulating layer 140 may be made of an insulating material including a black material, for example, by the pad printing method using black ink.

A seal member 150 for covering the side insulating layer 140 is disposed. The seal member 150 may be disposed to surround the side surface of the display device 100 to protect the display device 100 from an external impact, moisture, oxygen, or the like. For example, the seal member 150 may be made of polyimide (PI), polyurethane, epoxy, or acryl-based insulating material, but is not limited thereto.

An optical film MF is disposed on the seal member 150, the side insulating layer 140, and the first protective layer 117. The optical film MF may be a functional film for protecting the display device 100 and implementing higher-quality images. For example, the optical film MF may include a shatterproof film, an anti-glare film, an anti-reflecting film, a low-reflecting film, an OLED transmittance controllable film, a polarizer, or the like, but is not limited thereto.

Meanwhile, an edge of the seal member 150 and an edge of the optical film MF may be disposed collinearly. In the manufacturing process of the display device 100, the optical film MF with a larger size may be attached onto the first substrate 110, and the seal member 150 for covering the side insulating layer 140 may be formed. Thereafter, portions of the seal member 150 and the optical film MF may be cut by radiating a laser to the seal member 150 and the optical film MF to correspond to the edge of the display device 100. Therefore, the size of the display device 100 may be adjusted through a process of cutting outer portions of the seal member 150 and the optical film MF, and the edge of the display device 100 may be formed flat.

Hereinafter, mechanical structures of the display device 100 and the tiling display device TD according to the embodiment of the present specification will be described with reference to FIGS. 5 to 14.

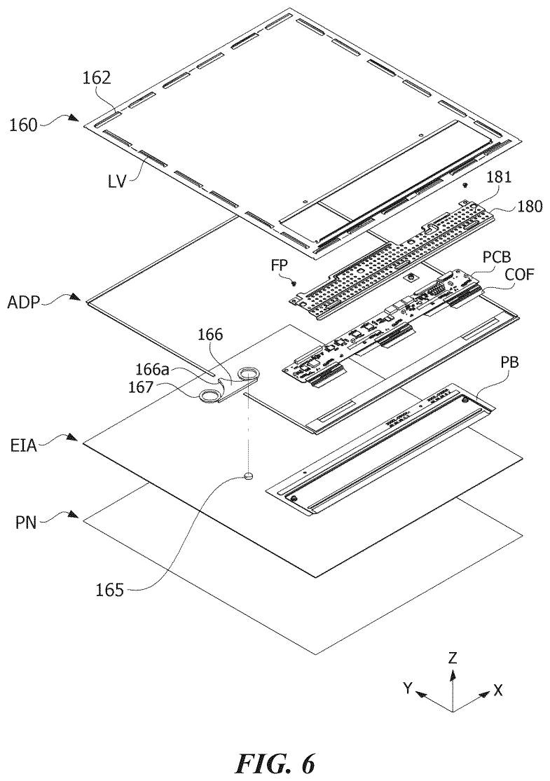

FIG. 6 is an exploded perspective view of a display module of the display device 100 according to one embodiment of the present specification.

Referring to FIG. 6, each of the display modules includes the display panel PN, the PCB disposed on the back surface of the display panel PN, the cover bottom 160 (or bottom cover 160), and the like.

The display module further includes a plurality of flexible films COF for connecting the second pad electrodes PAD2 disposed at the outermost portion of the back surface of the display panel PN to output terminals of the PCB. An IC with an integrated data driver DD and/or gate driving circuit may be mounted on at least one of the flexible films COF. The flexible films COF may be bonded to the back surface of the display panel PN through an anisotropic conductive film (ACF).

On the PCB disposed at one side, for example, a lower end of the display module, various circuit elements are disposed for driving the display panel PN. For example, devices used to generate various voltages, such as high potential power, low potential power, and reference power, that is, a power IC chip (or a PMIC), may be disposed on the PCB. The circuit elements disposed on the PCB may be heated upon driving. In particular, since a heating temperature of the power IC chip and an inductor is high, a temperature in the area where the PCB is disposed in the display module, for example, a temperature under the display module may increase, causing a temperature difference in the display panel PN. Such a temperature difference may act as a major factor which causes stains or color differences to be visible when images are displayed on the pixels of the display panel PN.

The PCB is electrically connected to the plurality of flexible films COF. Input terminals of the PCB may be electrically connected to output terminals. The plurality of lines and the plurality of circuit elements may be mounted on the PCB.

The display module may further include a plate bottom PB disposed under the PCB, and a cover shield 180 disposed above the PCB. The plate bottom PB and the cover shield 180 may be made of a material with high thermal conductivity and rigidity.

The plate bottom PB, the PCB, and the cover shield 180 may have at least one fastening hole overlapping each other, and a PEM bolt may be coupled to the fastening holes of the plate bottom PB, the PCB, and the cover shield 180 so that the plate bottom PB, the PCB, and the cover shield 180 may be coupled in a stacked structure.

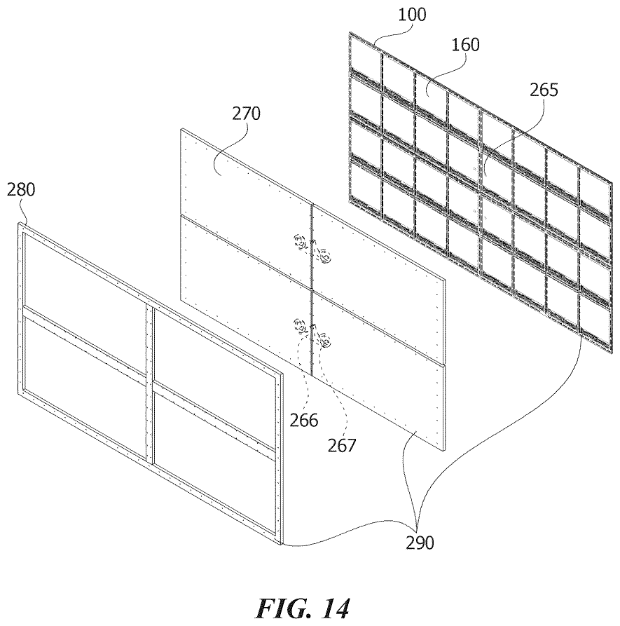

The cover bottom 160 may be made of a material with rigidity and high thermal conductivity, for example, a metal material, such as aluminum (Al), copper (Cu), zinc (Zn), silver (Ag), gold (Au), iron (Fe), a stainless steel, or Invar, or plastic. The cover bottom 160 may include a plurality of wings 162 protruding upward. The plurality of wings 162 may be formed by cutting a portion of the cover bottom 160 and then bending the cover bottom 160, but are not necessarily limited thereto. A plurality of display modules may be tiled by fixing the wings 162 to a cabinet 280 (see FIG. 14). However, the method of tiling the plurality of display modules is not necessarily limited thereto, and various coupling methods can be applied without limitation.

The plate bottom PB may distribute and dissipate the heat generated from the PCB. The plate bottom PB may be disposed between the PCB and the display panel PN to resolve a phenomenon in which the heat generated from the PCB is concentrated on a specific area of the display panel PN.

The cover shield 180 includes a plurality of heat dissipation holes 181 as shown in FIG. 6. The heat dissipation holes 181 may be disposed to be evenly distributed on the cover shield 180. The heat dissipation holes 181 may allow the heat generated from the PCB to be discharged to the outside through the cover shield 180. Among the heat distribution of the PCB, the cover shield 180 may be opened at a heating portion with a high temperature, for example, an IC or an inductor.

The first support EIA is disposed outside an area where the second pad electrode PAD2 and the flexible film COF are connected.

The first support EIA may be disposed between the display panel PN and the cover bottom 160, and the first support EIA may include a rod 165.

When the first support EIA is made of an organic insulating material or a metal material, the first support EIA may be formed in a shape including the rod 165, and the rod 165 may be attached to the first support EIA using an adhesive material.

The first support EIA may be attached to a lower surface of the display panel PN by a deposition process or using an adhesive material.

In other words, the cover bottom 160 may be attached to one surface of the first support EIA, that is, a surface opposite to the first support EIA to which the display panel PN is attached through an adhesive member ADP.

In addition, a portion of a rail 166 may be attached to the cover bottom 160. The rail 166 and the cover bottom 160 may be attached through an adhesive material, a double-sided tape, or the like, but are not limited thereto.

A portion of one rail 166 may be attached to one side portion of one cover bottom 160, and a portion of another rail 166 may be further attached to the other side portion of the one cover bottom 160.

A portion of the rail 166 may be attached to each of both sides of the one cover bottom 160.

In addition, the rail 166 and the first support EIA may be attached in an area where the rail 166 overlaps the first support EIA using an adhesive material or a double-sided tape.

Both side surfaces of the rail 166 are guide surfaces 166a, and the roller 167 may move along the guide surfaces 166a. The roller 167 may not be attached to the first support EIA and the cover bottom 160.

The rod 165 may be disposed in the roller 167, and the rod 165 may be in contact with an inner surface of the roller 167 so that the roller 167 may be supported by and rotated about the rod 165 as an axis.

The adhesive member ADP for attaching the first support EIA and the cover bottom 160 may not be positioned in the area where the rail 166 is disposed.

The rod 165, the rail 166, and the roller 167 may be made of plastic, acrylic, or a metal, and outer sides thereof may be coated with a low friction material such as Teflon.

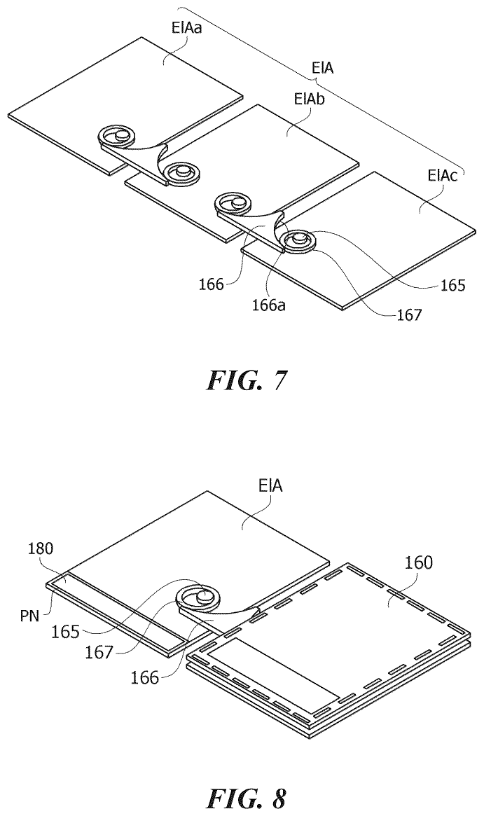

FIGS. 7 and 8 are partial plan views of the display device according to one embodiment of the present specification.

The rail 166 and the roller 167 can be described with reference to FIGS. 7 and 8.

The rail 166 and the roller 167 may be disposed between the first support EIA and the cover bottom 160.

As shown in FIG. 7, one rail 166 may be disposed on two first supports EIA, and the rod 165 and the roller 167 may be disposed on each first support EIA.

For example, when three first supports EIA are provided, two rails 166b may be disposed at the left and right sides of a first support EIAb positioned at the center, and the rod 165 and the roller 167 may be disposed at each of the left and right sides of the first support EIAb disposed at the center.

The cover bottom 160 may be disposed to overlap the first support EIA, and the rod 165, the rail 166, and the roller 167 may be disposed between the cover bottom 160 and the first support EIA.

The rail 166 may be disposed between cover bottoms 160 adjacent to each other in a left-right direction and between cover bottoms 160 adjacent to each other in a vertical direction, but is not limited thereto.

When the rail 166 is disposed between the cover bottoms 160 adjacent to each other in the vertical direction, the rail 166 has a 90-degree rotated shape, and the guide surfaces may be disposed on the upper and lower surfaces of the rail 166 to adjust a distance between the upper and lower cover bottoms 160.

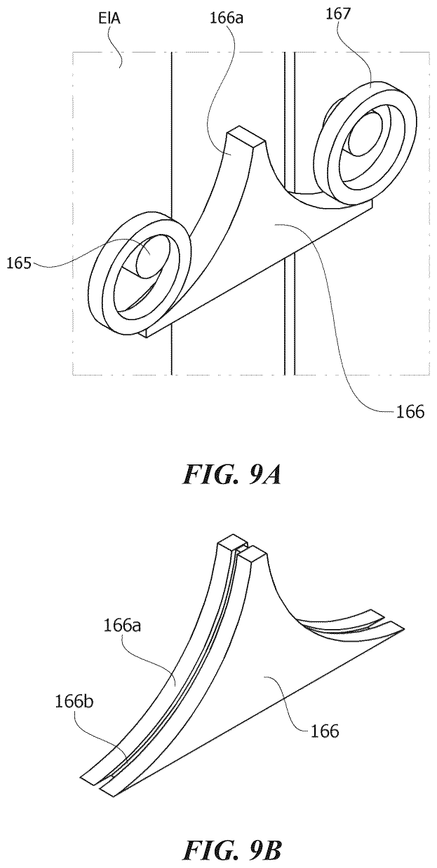

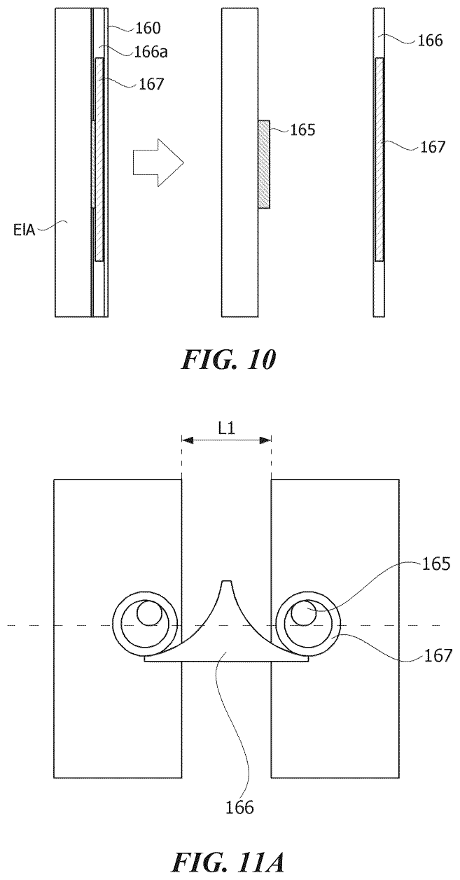

FIGS. 9A and 10 are an enlarged view and a side view of a portion of the display device according to one embodiment of the present specification.

Referring to FIGS. 9A and 10, the rod 165 is in contact with the inside of the roller 167, and the roller 167 slides along the guide surfaces 166a at both sides of the rail 166.

Although the rail 166 and the rod 165 may have a width which is the same as a distance between the cover bottom 160 and the first support EIA, and the roller 167 may have a smaller width than the rail 166 and the rod 165, the present specification is not limited thereto. In this case, a thickness of the rod 165 may be formed to be the same as or greater than the thickness of the roller 167. However, the present specification is not necessarily limited thereto.

Referring to FIG. 9B, a guide groove 166b may be formed on the guide surface 166a of the rail 166 to guide the movement of the roller 167. When the guide surface 166a has the guide groove 166b, a protrusion fitted into the guide groove 166b may be additionally present on an outer surface of the roller 167, but the present specification is not limited thereto.

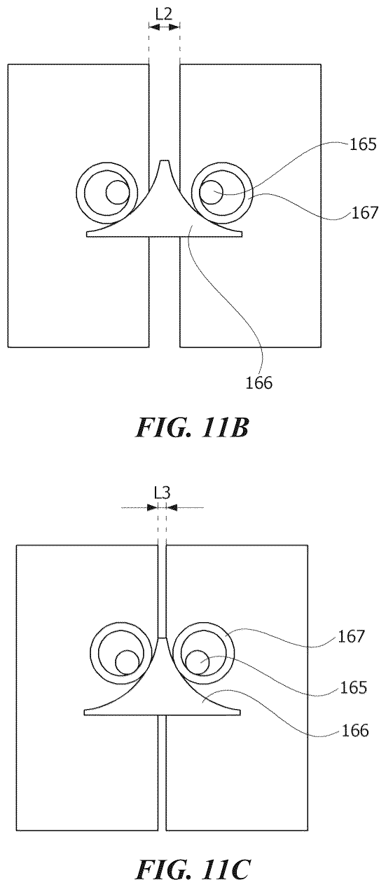

FIGS. 11A to 11C are schematic plan views of a thermal deformation process according to one embodiment of the present specification.

When the tiling display device TD, which is a large-area display device, is configured by tiling the display devices 100 including the display panel PN, heat may be generated due to the driving of the display device 100, the display panel PN may expand, and the distance between the display devices 100 may be changed.

After the distance between the display devices 100 decreases or increases due to thermal expansion, it may be difficult to maintain the existing position and the existing distance after the driving of the display device 100 is ended.

FIG. 11A is an example before thermal deformation occurs between the display devices 100.

A first distance L1 may be maintained between the display devices 100, the roller 167 may be positioned at both ends of the rail 166, and a lower end of the rod 165 may match a center line of the roller 167.

FIG. 11B is an example during thermal deformation of the display device 100.

The distance between the display devices 100 may be changed to a second distance L2 and may have a smaller length than the first distance L1.

In the thermal expansion process of the display panel PN, as the distance between the display devices 100 decreases, the rod 165 may move downward inside the roller 167, and the roller 167 may gradually move up along the guide surface 166a of the rail 166.

Since the roller 167 moves only in the guide surface 166a, it is possible to minimize interference between the display panels PN due to thermal expansion. When thermal expansion occurs, as shown in FIG. 11C, the distance between the display devices 100 may be a third distance L3. The third distance L3 may be smaller than the second distance L2.

The third distance L3 is the smallest distance between the display devices 100, and in this case, the roller 167 may be disposed at an upper side of the rail 166, and the rod 165 may be positioned at an inner lower end of the roller 167.

After the driving of the display device 100 is ended, the display device 100, which has been thermally expanded, may shrink to a state before thermal deformation.

Upon shrinkage, the display devices 100 may have the first distance L1 as the roller 167 moves along the guide surface 166a of the rail 166.

Since the change in the distance and alignment between the display devices 100 due to thermal expansion and shrinkage of the display devices 100 occurs when the roller 167 is only in the guide surface 166a of the rail 166, it is possible to minimize the influence of interference between the display devices 100 and return to the distance between the display devices 100 in a non-driving state.

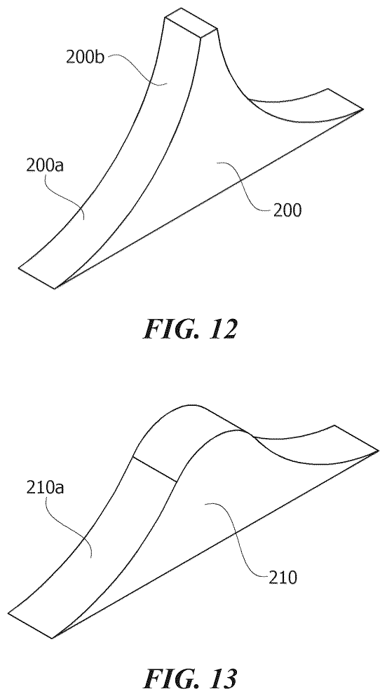

FIGS. 12 and 13 are views of rails 200 and 210 according to another embodiment of the present specification.

Referring to FIG. 12, a side surface of the rail 200 may have two or more multiple curves. A first guide surface 200a may have a gentle slope, and a second guide surface 200b may have a steeper slope than the first guide surface 200a.

Referring to FIG. 13, a guide surface 210a at a side surface of the rail 210 may have an S curve that is a curve similar to S. An uppermost portion of the rail 210 may have a gentle slope, and a lower portion has a steeper slope than the upper portion.

The rails 200 and 210 with various slopes in the embodiments of FIGS. 12 and 13 may change a downwardly moving speed of the roller according to the slope, and thus a length and speed can be adjusted in a limited space.

FIG. 14 is an exploded perspective view of a display device according to another embodiment of the present specification. In describing the components of FIG. 14, descriptions of components which are the same as or correspond to those of FIG. 6 will be omitted or simplified.

Referring to FIG. 14, a large-area tiling display device TD may be formed by attaching a plurality of display devices 100 to one back cover 270 and fixing a plurality of back covers 270 using the cabinet 280.

When the plurality of display devices 100 are attached to the back cover 270, the plurality of display devices 100 may be attached using an adhesive material or connected using bolts or the like through fastening holes 290.

The cover bottom 160, the back cover 270, and the cabinet 280 may be formed with the fastening holes 290 and coupled using a resin or bolts, but are not limited thereto.

A rod 265 may be disposed on the cover bottom 160 attached to the lower surface of the display panel PN, a rail 266 may be disposed on the back cover 270, and a roller 267 may be disposed between the cover bottom 160 and the back cover 270. The fastening hole 290 may not be formed in an area where the rail 266 and the rod 265 are disposed.

When the distance between the display devices 100 is changed, the roller 267 may rotate while in contact with the rod 265 to move along a guide surface of the rail 266 and then return to an initial position.

The rail 266 may be disposed between back covers 270 adjacent to each other in a left-right direction and between back covers 270 adjacent to each other in a vertical direction, but is not limited thereto.

When the rail 266 is disposed between the back covers 270 adjacent to each other in the vertical direction, the rail 266 has a 90-degree rotated shape, and the guide surfaces may be disposed on upper and lower surfaces of the rail 266 to align a distance between the upper and lower back covers 270.

According to some embodiments of the present specification, the display device may include a display panel including a display area where a plurality of sub-pixels are disposed and a non-display area, a back cover disposed under the display panel, and a roller and a rail disposed between the display panel and the back cover, wherein the rail may be disposed between two display panels, and the roller may be disposed on each of two side surfaces of each rail.

According to some embodiments of the present specification, the display device may further include a cover bottom disposed between the display panel and the back cover.

According to some embodiments of the present specification, the rail may be attached to the cover bottom.

According to some embodiments of the present specification, the display device may include the first support disposed between the display panel and the cover bottom and the rod disposed on the first support.

According to some embodiments of the present specification, the rod may be disposed in the roller and may be in contact with the inner surface of the roller.

According to some embodiments of the present specification, the display device may include the rod disposed on the cover bottom.

According to some embodiments of the present specification, the rail may be attached to the back cover.

According to some embodiments of the present specification, the rail may be disposed between the display panels adjacent to each other in the left-right direction or the vertical direction.

According to some embodiments of the present specification, the clock line, the gate high potential power supply voltage line, and the gate low potential power supply voltage line may be disposed on the same layer.

According to some embodiments of the present specification, the back cover may correspond to two or more display panels.

According to some embodiments of the present specification, the roller may be in contact with the guide surface of the rail.

According to some embodiments of the present specification, the roller may move along the guide surface.

According to some embodiments of the present specification, a guide groove into which the roller may be fitted may be further included in the guide surface.

According to some embodiments of the present specification, the width of the roller may be smaller than or equal to the width of the side surface of the rail.

According to some embodiments of the present specification, the rail may have multiple curves or an S-curve.

According to some embodiments of the present specification, the thickness of the rod may be greater than or equal to the thickness of the roller.

According to some embodiments of the present specification, the sub-pixel may include a micro LED.

According to some embodiments of the present specification, the display panel includes the first pad electrode disposed on one surface of the substrate, the second pad electrode disposed on the other surface of the substrate, and the side line for connecting the first pad electrode with the second pad electrode.

According to some embodiments of the present specification, the display panel may include the seal member for covering the side line and the optical film disposed on the substrate.

According to some embodiments of the present specification, the edge of the seal member and the edge of the optical film may be disposed collinearly.

According to some embodiments of the present specification, the cover bottom may include a plurality of protruding wings.

According to embodiments of the present specification, since a roller and a rail are provided, it is possible to easily restore a distance between display panels in a display device in which a plurality of display panels are tiled.

According to embodiments of the present specification, since a rod and the roller are provided, it is possible to simply align locations of the display panel, a cover bottom, and a cabinet when the display panel and the cover bottom or the cover bottom and a cabinet are deformed and restored.

The effects of the present specification are not limited to the above-described effects, and other effects that are not mentioned will be able to be clearly understood by those skilled in the art from the following description.

Since the contents of the specification described in the above-described technical problem, technical solution, and advantageous effects do not specify the essential features of the claims, the scope of the claims is not limited by the items described in the contents of the specification.

The above description is merely the exemplary description of the technical spirit of the present disclosure, and those skilled in the art to which the present disclosure pertains will be able to variously modify and change the present disclosure without departing from the essential characteristics of the present disclosure. Therefore, the embodiments disclosed in the present disclosure are not intended to limit the technical spirit of the present disclosure, but are to describe the same, and the scope of the technical spirit of the present disclosure is not limited by these embodiments.

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a display panel including a display area and a non-display area, the display area including a plurality of sub-pixels;
a back cover disposed under the display panel; and
a roller and a rail disposed between the display panel and the back cover,
wherein the roller is disposed on one side surface of the rail, and
wherein the rail extends from the roller of the display panel and is configured to be disposed on a roller of at least one further display panel.

2. The display device of claim 1, further comprising a bottom cover disposed between the display panel and the back cover.

3. The display device of claim 2, wherein the rail is attached to the bottom cover.

4. The display device of claim 3, further comprising a first support disposed between the display panel and the bottom cover and a rod disposed on the first support.

5. The display device of claim 4, wherein the roller is disposed on the rod and the rod is in contact with an inner surface of the roller.

6. The display device of claim 2, further comprising a rod disposed on the bottom cover.

7. The display device of claim 6, wherein the rail is attached to the back cover.

8. The display device of claim 1, wherein the rail is disposed between the display panel and the further display panel, and wherein the display panel and the further display panel are adjacent to each other in a left-right direction or adjacent to each other in a vertical direction.

9. The display device of claim 1, wherein the back cover corresponds to the display panel and the further display panel.

10. The display device of claim 1, wherein the roller is in contact with a guide surface of the rail.

11. The display device of claim 10, wherein the roller is movable along the guide surface.

12. The display device of claim 11, wherein the guide surface further includes a guide groove and the roller is fitted into the guide groove.

13. The display device of claim 10, wherein a width of the roller is smaller than or equal to a width of the side surface of the rail.

14. The display device of claim 1, wherein the rail has multiple curves or an S curve.

15. The display device of claim 5, wherein a thickness of the rod is greater than or equal to a thickness of the roller.

16. The display device of claim 1, wherein the sub-pixel includes a micro light emitting diode (LED).

17. The display device of claim 1, wherein the display panel includes:
a first pad electrode disposed on a first surface of a substrate;
a second pad electrode disposed on a second surface of the substrate, wherein the second surface is opposite to the first surface of the substrate; and
a side line connecting the first pad electrode and the second pad electrode.

18. The display device of claim 17, wherein the display panel includes:
a seal member covering the side line; and
an optical film disposed on the substrate.

19. The display device of claim 18, wherein an edge of the seal member and an edge of the optical film are disposed collinearly.

20. The display device of claim 2, wherein the cover bottom includes a plurality of protruding wings.

21. A display system, comprising:
a plurality of display devices, each including:
a display panel;
a cover under the display panel; and
a roller disposed between the display panel and the cover; and
a rail extending between two successive display devices of the plurality of display devices, wherein the rail is in contact with the roller of both of the two successive display devices.

22. The display system of claim 21, wherein the rail is disposed between the display panel and the cover of both of the two successive display devices.

23. The display system of claim 21, wherein the two successive display devices are adjacent to each other in a left-right direction or adjacent to each other in a vertical direction.

24. The display system of claim 21, wherein the roller of each of the two successive display devices is configured to rotate along the rail, and wherein movement of the roller of the two successive display devices along the rail varies a distance between the two successive display devices.
